(19) United States
(12) Patent Application Publication
(10) Pub. No.: US 2009/0262771 A1
(43) Pub. Date: Oct. 22, 2009

(54) SEMICONDUCTOR LASER DEVICE AND METHOD OF MANUFACTURING THE SAME

(75) Inventors: Daijiro Inoue, Kyoto (JP); Yasuyuki Bessho, Kyoto (JP); Masayuki Hata, Osaka (JP); Yasuhiko Nomura, Osaka (JP); Seiichi Tokunaga, Osaka (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/090,334

(22) PCT Filed: Jul. 31, 2007
(86) PCT No.: PCT/JP2007/064921

§ 371 Date: Apr. 15, 2008

(30) Foreign Application Priority Data
Jul. 31, 2006 (JP) 2006-208403
Jul. 30, 2007 (JP) 2007-197704

(51) Int. Cl. H01S 5/026; H01L 21/00

(52) U.S. Cl. 372/45.01; 438/31; 257/E21.002; 438/33

(57) ABSTRACT

A semiconductor laser device capable of suppressing damage of a waveguide is obtained. This GaN-based semiconductor laser chip (semiconductor laser device) includes an n-type GaN substrate of a nitride-based semiconductor and a semiconductor layer of a nitride-based semiconductor formed on the n-type GaN substrate and provided with a ridge portion constituting a waveguide extending in a direction F. The ridge portion (waveguide) is formed on a region approaching a first side from the center of the semiconductor layer. On a region opposite to the first side of the ridge portion (waveguide), a cleavage introduction step is formed from the side of the semiconductor layer, to extend in a direction intersecting with the extensional direction F of the ridge portion (waveguide).

### TECHNICAL FIELD

The present invention relates to a semiconductor laser device and a method of manufacturing the same, and more particularly, it relates to a semiconductor laser device comprising a semiconductor layer provided with a waveguide and a method of manufacturing the same.

### BACKGROUND ART

In general, Japanese Patent Laying-Open No. 2003-17791 discloses a nitride-based semiconductor laser device comprising a semiconductor layer provided with a striped waveguide.

FIG. 25 is a perspective view showing the structure of the conventional nitride-based semiconductor laser device comprising the semiconductor layer provided with the striped waveguide disclosed in Japanese Patent Laying-Open No. 2003-17791. Referring to FIG. 25, a semiconductor layer 102 having a ridge portion 102a constituting a striped waveguide is formed on a GaN-based substrate 101 in the conventional nitride-based semiconductor laser device disclosed in the aforementioned Patent Document 1. This ridge portion 102a is provided at the center of the nitride-based semiconductor laser device in the cross direction (direction G). A p-side electrode 103 is provided on the semiconductor layer 102. An n-side electrode 104 in ohmic contact with the GaN-based substrate 101 is provided on the back surface of the GaN-based substrate 101. Two mirror facets 105 and 106 consisting of cleavage planes are formed to be orthogonal to the ridge portion 102a. These two mirror facets 105 and 106 constitute a cavity.

Grooving portions 107 for cleavage introduction are formed on the GaN-based substrate 101, the semiconductor layer 102 and the p-side electrode 103. These grooving portions 107 are formed on the two mirror facets 105 and 106 consisting of the cleavage planes along a direction orthogonal to the ridge portion 102a at the same distance in the direction G leftwardly and rightwardly from the ridge portion 102a, to hold the ridge portion 102a provided at the center therebetween. In other words, the grooving portions 107 are horizontally symmetrically formed with respect to the ridge portion 102a.

In this nitride-based semiconductor laser device, a metal wire 108 for supplying power to the p-side electrode 103 is wire-bonded to the p-side electrode 103.

In general, the metal wire 108 is usually wire-bonded to the center of the p-side electrode 103. Particularly when the length in the cross direction (direction G) is reduced due to downsizing of the nitride-based semiconductor laser device, the bonding position must be matched with the center, in order to increase allowance (margin) with respect to displacement in wire bonding.

In the structure of the conventional nitride-based semiconductor laser device disclosed in Japanese Patent Laying-Open No. 2003-17791, however, the ridge portion 102a is formed at the center of the nitride-based semiconductor laser device, whereby the metal wire 108 is bonded to a portion immediately above the ridge portion 102a provided at the center when the metal wire 108 is bonded to the p-side electrode 103, if the length of the nitride-based semiconductor laser device in the cross direction (direction G) is reduced. Therefore, there is such a problem that the ridge portion 102a (waveguide) may be damaged in bonding of the metal wire 108 to deteriorate laser characteristics.

### DISCLOSURE OF THE INVENTION

The present invention has been proposed in order to solve the aforementioned problem, and an object of the present invention is to provide a semiconductor laser device capable of suppressing damage of a waveguide and a method of manufacturing the same.

A semiconductor laser device according to a first aspect of the present invention comprises a substrate of a nitride-based semiconductor and a semiconductor layer of a nitride-based semiconductor formed on the substrate and provided with a waveguide extending in a prescribed direction, while the waveguide is formed on a region approaching a first side from the center of the semiconductor layer, and a first step is formed from the side of the semiconductor layer on a region opposite to the first side of the waveguide at a prescribed distance from the waveguide, to extend in a direction intersecting with the prescribed extensional direction of the waveguide on an extension of an end surface of the waveguide.

In the semiconductor laser device according to the first aspect of the present invention, as hereinabove described, the waveguide extending in the prescribed direction is formed on the region approaching the first side from the center of the semiconductor layer so that a metal wire can be inhibited from being bonded onto the waveguide in a case of bonding the metal wire to the center of the upper surface side of the semiconductor layer in order to supply power to the upper surface side of the semiconductor layer, whereby damage of the waveguide can be suppressed in bonding. Thus, deterioration of laser characteristics can be suppressed. Further, the first step is formed from the side of the semiconductor layer on the region opposite to the first side of the waveguide at the prescribed interval from the waveguide so that the first step can be formed on a position separated from the waveguide, whereby damage of the waveguide can be suppressed when the first step is formed from the side of the semiconductor layer. Deterioration of the laser characteristics can be suppressed also by this.

In the aforementioned semiconductor laser device according to the first aspect, the first step is preferably formed from the side of the semiconductor layer up to a depth reaching the substrate. According to this structure, not only the semiconductor layer but also the substrate can be easily cleaved when forming a cavity facet by cleavage.

In the aforementioned semiconductor laser device according to the first aspect, the first step is preferably so formed that the width in the direction intersecting with the prescribed extensional direction of the waveguide is increased upward. According to this structure, energy for forming an end of the first step by laser application or the like can be reduced below energy for forming the bottom of the first step by laser application or the like, whereby a bad influence on the waveguide close to the end of the first step can be suppressed, and deterioration of the waveguide can be suppressed.

The aforementioned semiconductor laser device according to the first aspect preferably further comprises a first electrode layer formed on the semiconductor layer, and the first electrode layer is preferably formed at a prescribed interval from the first step. According to this structure, the first electrode layer and the first step are formed at the prescribed interval, whereby a leakage current can be inhibited from increase resulting from adhesion of a material constituting the first electrode layer to the first step portion also when a conductive material constituting the first electrode layer scatters.

In the aforementioned structure, the waveguide is preferably arranged on a position separated from the center of the semiconductor laser device by at least about 20 μm. According to this structure, a feeder wire can be connected to the center of the semiconductor laser device while avoiding damage on the waveguide also when a generally employed feeder wire of about 30 μm in diameter is employed on a surface on the side of the semiconductor layer.

In the aforementioned semiconductor laser device according to the first aspect, a second step is preferably formed from the side of the substrate along the prescribed extensional direction of the waveguide.

In this case, the second step is preferably so formed as to have a length substantially identical to the length between a first end surface and a second end surface of the waveguide. According to this structure, separation can be reliably performed in the extensional direction of the second step when forming a laser device chip by separation.

In the aforementioned structure having the second step formed from the side of the substrate, the semiconductor laser device preferably further comprises a second electrode layer on the lower surface of the substrate, and the second step is preferably so formed as to have a depth reaching a part of the lower surface of the substrate from the side of the second electrode layer. According to this structure, separation in formation of the laser device chip can be easily performed through the second step.

In the aforementioned semiconductor laser device according to the first aspect, a third step is preferably formed from the side of the substrate on the end surface of the waveguide, to extend in the direction intersecting with the prescribed extensional direction of the waveguide. According to this structure, not only cleavage from the side of the semiconductor layer provided with the first step but also cleavage from the side of the substrate provided with the third step can be easily performed. Thus, cleavage can be more easily executed.

In the aforementioned semiconductor laser device according to the first aspect, the third step is preferably provided on a position opposite to at least the waveguide or the first step. According to this structure, the portion for forming the third step is more shortened when the third step is opposed to only the waveguide, whereby abrasion of a scriber such as a diamond point, for example, can be suppressed. When the third step is opposed to only the first step, on the other hand, the third step is not formed on a position opposite to the waveguide, whereby an impact following scribing with a diamond point or the like can be inhibited from influencing the waveguide.

In this case, the third step is preferably so formed as to have a length substantially identical to the length between a first end surface and a second end surface in the direction intersecting with the prescribed extensional direction of the waveguide. According to this structure, cleavage can be more easily performed through the third step formed on the overall region in the direction intersecting with the prescribed extensional direction of the waveguide.

A method of manufacturing a semiconductor laser device according to a second aspect of the present invention comprises steps of forming a semiconductor layer of a nitride-based semiconductor including a plurality of waveguides extending in a prescribed direction on a substrate of a nitride-based semiconductor, forming a plurality of first cleavage introduction recess portions from the side of the semiconductor layer between the plurality of waveguides to extend in a direction intersecting with the prescribed extensional direction of the waveguides, performing cleavage along the plurality of first cleavage introduction recess portions and performing separation along the prescribed extensional direction of the waveguide so that the semiconductor laser device has the waveguides on a region approaching a first side from the center of the semiconductor layer.

In the method of manufacturing a semiconductor laser device according to the second aspect of the present invention, as hereinabove described, the step of performing separation so that the semiconductor laser device has the waveguides on the region approaching the first side from the center of the semiconductor layer is so provided that bonding of a metal wire onto the waveguides can be suppressed in a case of bonding the metal wire to the center of the upper surface side of the semiconductor layer in order to supply power to the upper surface side of the semiconductor layer, whereby damage of the waveguides can be suppressed in bonding. Thus, deterioration of laser characteristics can be suppressed.

In the aforementioned method of manufacturing a semiconductor laser device according to the second aspect, the step of forming the semiconductor layer of the nitride-based semiconductor including the plurality of waveguides preferably includes a step of forming the plurality of waveguides to alternately have two different intervals, and the step of forming the first cleavage introduction recess portions preferably includes a step of forming the first cleavage introduction recess portions between adjacent waveguides having a larger interval in the two different intervals.

In the aforementioned method of manufacturing a semiconductor laser device according to the second aspect, the step of forming the first cleavage introduction recess portions preferably includes a step of forming the first cleavage introduction recess portions from the side of the semiconductor layer up to a depth reaching the substrate. According to this structure, not only the semiconductor layer but also the substrate can be easily cleaved in the step of performing cleavage along the first cleavage introduction recess portions.

In the aforementioned method of manufacturing a semiconductor laser device according to the second aspect, the step of forming the first cleavage introduction recess portions preferably includes a step of forming the first cleavage introduction recess portions so that the width in the direction intersecting with the prescribed extensional direction of the waveguides is increased upward. According to this structure, energy for forming ends of the first cleavage introduction recess portions by laser application or the like can be reduced below energy for forming the bottoms of the first cleavage introduction recess portions by laser application or the like, whereby a bad influence on the waveguides close to the ends of the first cleavage introduction recess portions can be suppressed, and a semiconductor laser device inhibited from deterioration of waveguides can be obtained.

In the aforementioned step of forming the plurality of waveguides, the step of forming the plurality of waveguides preferably includes a step of forming the plurality of waveguides so that a region having a large number of crystal defects of at least either one of the substrate and the semiconductor layer is positioned between adjacent waveguides having a larger interval in the two different intervals.

The aforementioned method of manufacturing a semiconductor laser device according to the second aspect preferably further comprises a step of forming a separation introduction recess portion from the side of the substrate along the prescribed extensional direction of the waveguides in advance of the step of performing separation along the prescribed extensional direction of the waveguides. According to this structure, separation can be reliably performed in the extensional direction of the separation introduction recess portion in the step of performing separation along the prescribed extensional direction of the waveguides.

In this case, the step of forming the separation introduction recess portion from the side of the substrate preferably includes a step of forming the separation introduction recess portion to have a length substantially identical to the length between first end surfaces and second end surfaces of the waveguides. According to this structure, separation can be reliably performed through the separation introduction recess portion formed on the overall region in the prescribed extensional direction of the waveguides when separating the device.

The aforementioned method of manufacturing a semiconductor laser device according to the second aspect preferably comprises a step of further forming a second cleavage introduction recess portion on the lower surface of the substrate to extend in the same direction as the prescribed extensional direction of the first cleavage introduction recess portions in advance of performing cleavage along the plurality of first cleavage introduction recess portions. According to this structure, not only cleavage from the side of the semiconductor layer provided with the first cleavage recess portions but also cleavage from the side of the substrate provided with the second cleavage introduction recess portion can be easily performed. Thus, cleavage can be more easily executed.

In this case, the step of forming the second cleavage introduction recess portion on the lower surface of the substrate preferably includes a step of forming the second cleavage introduction recess portion on a position opposite to at least the waveguides or the first cleavage introduction recess portions. According to this structure, the portion for forming the second cleavage introduction recess portion is more shortened when the second cleavage introduction recess portion is so formed that the second cleavage introduction recess portion is opposed to only the waveguides, whereby abrasion of a scriber such as a diamond point, for example, can be suppressed. When the second cleavage introduction recess portion is so formed that the second cleavage introduction recess portion is opposed to only the first cleavage introduction recess portions, on the other hand, the second cleavage introduction recess portion is not formed on a position opposite to the waveguides, whereby an impact following scribing with a diamond point or the like can be inhibited from influencing the waveguides.

In the aforementioned method of manufacturing a semiconductor laser device according to the second aspect, the step of performing separation along the prescribed extensional direction of the waveguides preferably includes a step of performing separation so that the semiconductor laser device has the waveguides on the region approaching the first side from the center of the semiconductor layer and has the first cleavage introduction recess portions on a region opposite to the first side of the waveguides. According to this structure, the first cleavage introduction recess portions can be formed on positions separated from the waveguides, whereby damage of the waveguides can be suppressed when the first cleavage introduction recess portions are formed from the side of the semiconductor layer. Deterioration of the laser characteristics can be suppressed also by this. According to the aforementioned structure, further, the size of the semiconductor laser device is increased by the region of the portion having the first cleavage introduction recess portions, whereby the device can be easily handled in the manufacturing process.

### BRIEF DESCRIPTION OF THE DRAWINGS

FIG. 1 A perspective view for illustrating the concept of the present invention.

FIG. 2 A perspective view showing the structure of a GaN-based semiconductor laser chip according to a first embodiment of the present invention.

FIG. 3 A sectional view showing the detailed structure of a semiconductor layer of the GaN-based semiconductor laser chip shown in FIG. 2.

FIG. 4 A perspective view for illustrating a manufacturing process (wafer process) in a wafer state of the GaN-based semiconductor laser chip according to the first embodiment shown in FIG. 2.

FIG. 5 A perspective view for illustrating the manufacturing process (wafer process) in the wafer state of the GaN-based semiconductor laser chip according to the first embodiment shown in FIG. 2.

FIG. 6 A plan view for illustrating a manufacturing process (singulation process) subsequent to the wafer process for the GaN-based semiconductor laser chip according to the first embodiment shown in FIG. 2.

FIG. 7 A sectional view for illustrating the manufacturing process (singulation process) subsequent to the wafer process for the GaN-based semiconductor laser chip according to the first embodiment shown in FIG. 2.

FIG. 8 A plan view for illustrating the manufacturing process (singulation process) subsequent to the wafer process for the GaN-based semiconductor laser chip according to the first embodiment shown in FIG. 2.

FIG. 9 A sectional view for illustrating the manufacturing process (singulation process) subsequent to the wafer process for the GaN-based semiconductor laser chip according to the first embodiment shown in FIG. 2.

FIG. 10 A perspective view showing the structure of a GaN-based semiconductor laser chip according to a first modification of the first embodiment of the present invention.

FIG. 11 A perspective view showing the structure of a GaN-based semiconductor laser chip according to a second modification of the first embodiment of the present invention.

FIG. 12 A perspective view showing the structure of a GaN-based semiconductor laser chip according to a third modification of the first embodiment of the present invention.

FIG. 13 A perspective view showing the structure of a GaN-based semiconductor laser chip according to a fourth modification of the first embodiment of the present invention.

FIG. 14 A perspective view showing the structure of a GaN-based semiconductor laser chip according to a second embodiment of the present invention.

FIG. 15 A plan view for illustrating a manufacturing process for the GaN-based semiconductor laser chip according to the second embodiment shown in FIG. 14.

FIG. 16 A plan view for illustrating a manufacturing process (singulation process) subsequent to a wafer process for the GaN-based semiconductor laser chip according to the second embodiment shown in FIG. 14.

FIG. 17 A perspective view showing the structure of a GaN-based semiconductor laser chip according to a third embodiment of the present invention.

FIG. 18 A plan view for illustrating a manufacturing process for the GaN-based semiconductor laser chip according to the third embodiment shown in FIG. 17.

FIG. 19 A plan view for illustrating a manufacturing process (singulation process) subsequent to a wafer process for the GaN-based semiconductor laser chip according to the third embodiment shown in FIG. 17.

FIG. 20 A perspective view showing the structure of a GaN-based semiconductor laser chip according to a fourth embodiment of the present invention.

FIG. 21 A perspective view showing the structure of the GaN-based semiconductor laser chip according to the fourth embodiment of the present invention.

FIG. 22 A plan view showing the structure of the GaN-based semiconductor laser chip according to the fourth embodiment shown in FIGS. 20 and 21.

FIG. 23 An enlarged sectional view around a first cleavage introduction recess portion formed through the manufacturing process for the GaN-based semiconductor laser chip according to the fourth embodiment shown in FIGS. 20 and 21.

FIG. 24 A diagram showing results of investigating crack formation rates between cleavage introduction recess portions and yield rates of cleavage in manufacturing steps for the GaN-based semiconductor laser chip according to the fourth embodiment shown in FIGS. 20 and 21.

FIG. 25 A perspective view showing the structure of a conventional nitride-based semiconductor laser device comprising a semiconductor layer provided with a striped waveguide disclosed in Japanese Patent Laying-Open No. 2003-17791.

### BEST MODES FOR CARRYING OUT THE INVENTION

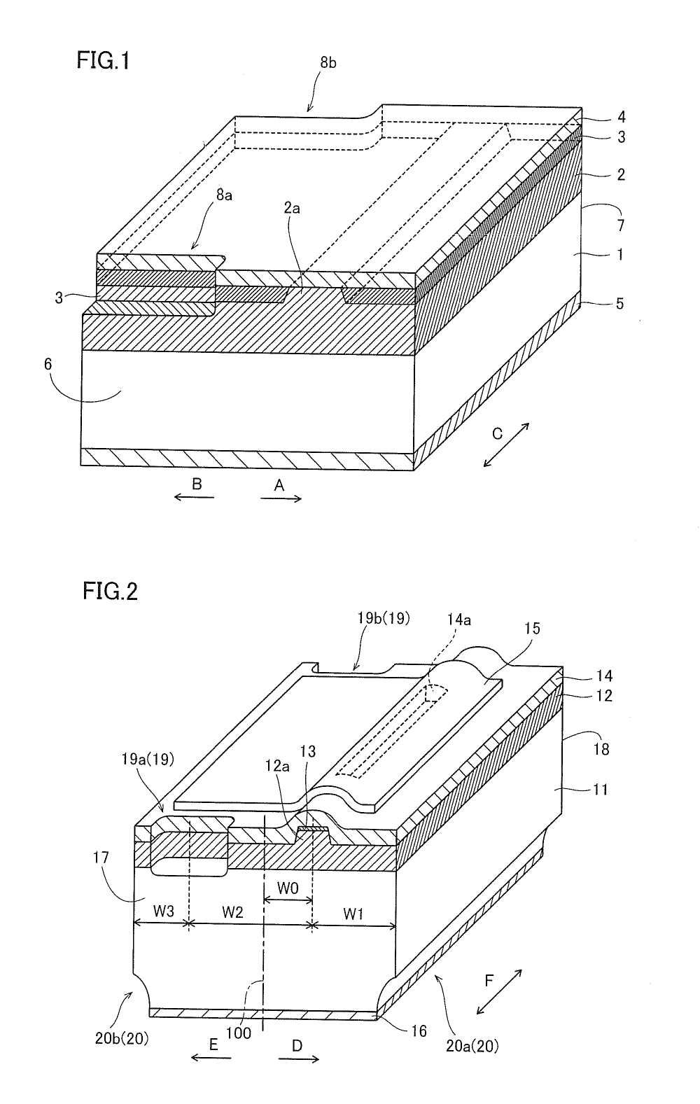

The concept of the present invention is described with reference to FIG. 1, before describing specific embodiments of the present invention.

In a semiconductor laser device according to the present invention, a semiconductor layer 2 having a current injection region 2a constituting a waveguide extending in a prescribed direction (direction C) is formed on a substrate 1 in a region approaching a first side (along arrow A) from the center of the substrate 1, as shown in FIG. 1. A current blocking layer 3 is formed on the semiconductor layer 2 except the upper surface of the current injection region 2a. A first electrode 4 in ohmic contact with the current injection region 2a of the semiconductor layer 2 is provided on the current blocking layer 3. A second electrode 5 in ohmic contact with the substrate 1 is provided on the back surface of the substrate 1. Two cleavage planes 6 and 7 are formed to be orthogonal to the current injection region 2a (waveguide).

Cleavage introduction steps (first steps) 8a and 8b for performing cleavage are formed on the semiconductor layer 2, the current blocking layer 3 and the first electrode 4. These cleavage introduction steps (first steps) 8a and 8b are formed only on a region opposite (along arrow B) to the first side (along arrow A) of the current injection region 2a (waveguide) at a prescribed interval from the current injection region 2a (waveguide), to extend in a direction (along arrow A (along arrow B)) orthogonal to the current injection region 2a (waveguide).

The substrate 1 consists of a semiconductor having a hexagonal structure containing a nitride, and consists of GaN, AlN, InN, BN, TlN or mixed crystals of these. The substrate 1 may have n-type conductivity, or may have p-type conductivity. In relation to the plane orientation of the substrate 1, a substrate of a {0001} plane, a {11-22} plane, a {11-20} plane or a {1-100} plane can be employed. In this case, the cleavage planes 6 and 7 are preferably formed by the {1-100} plane or the {0001} plane, in view of planarity of the cleavage planes 6 and 7 and easiness in cleavage.

The semiconductor layer 2 includes at least a layer of a conductivity type different from that of the substrate 1. This semiconductor layer 2 may include an active layer. In this case, the semiconductor layer 2 may have the layer of the conductivity type different from that of the substrate 1 on the surface of the active layer opposite (upper side) to the substrate 1. Further, the active layer may be held between two layers of conductivity types different from each other, having larger band gaps than the active layer. In this case, one of the two layers of conductivity types different from each other may be the substrate 1.

The current injection region 2a may be formed by a ridge portion having a convex sectional shape as shown in FIG. 1, or an opening (not shown) extending in the direction C may be provided on the current blocking layer 3 without providing the convex ridge portion, for connecting the current injection region 2a defined by the opening and the first electrode 4 with each other through the opening.

The current injection region 2a is preferably formed along the <1-100> direction (direction C) orthogonal to the {1-100} plane which is the plane orientation capable of obtaining an excellent cleavage plane.

The semiconductor layer 2 consists of a semiconductor having a hexagonal structure containing a nitride, and consists of GaN, AlN, InN, BN, TlN or mixed crystals of these. The band gaps of the respective layers (the layer of the conductivity type different from that of the substrate 1, the active layer, the two layers of conductivity types different from each other etc.) constituting the semiconductor layer 2 can be set to desired values by varying the ratios of the materials and the mixed crystals constituting the layers.

Carbon, oxygen, silicon, sulfur, germanium, selenium or tellurium can be employed as a dopant introduced into an n-type substrate 1 and n-type layers of the semiconductor layer 2, while beryllium, magnesium or zinc can be employed as a dopant introduced into a p-type substrate 1 and p-type layers of the semiconductor layer 2.

The current blocking layer 3 is employed for blocking current injection into the regions other than the current injection region 2a, and can be formed by an insulator or a high-resistance material. More specifically, an oxide or a nitride of aluminum, silicon, titanium, zinc, gallium, zirconium, indium or hafnium can be employed.

The first electrode 4 and the second electrode 5 are ohmic electrodes for supplying power to the current injection region 2a and the substrate 1 respectively, and both made of materials having conductivity. The first electrode 4 and the second electrode 5 may be constituted of aluminum, silicon, titanium, chromium, nickel, germanium, rhodium, palladium, silver, indium, tin, platinum, gold or an alloy thereof, or multilayer structures obtained by stacking layers of these. The first electrode 4 and the second electrode 5 may be formed at prescribed intervals from the cleavage planes 6 and 7. Further, the first electrode 4 and the second electrode 5 may be formed at prescribed intervals from the side surfaces (side surfaces parallel to the waveguide) of the device.

The cleavage introduction steps (first steps) 8a and 8b are recess portions for normally performing cleavage, and may be formed by scratching with a hard tool such as a diamond point having a sharp forward end, or may be formed by applying a beam such as a laser beam or an ion beam having high energy to only desired regions thereby evaporating the material of these portions.

Embodiments embodying the aforementioned concept of the present invention are now described with reference to the drawings.

### First Embodiment

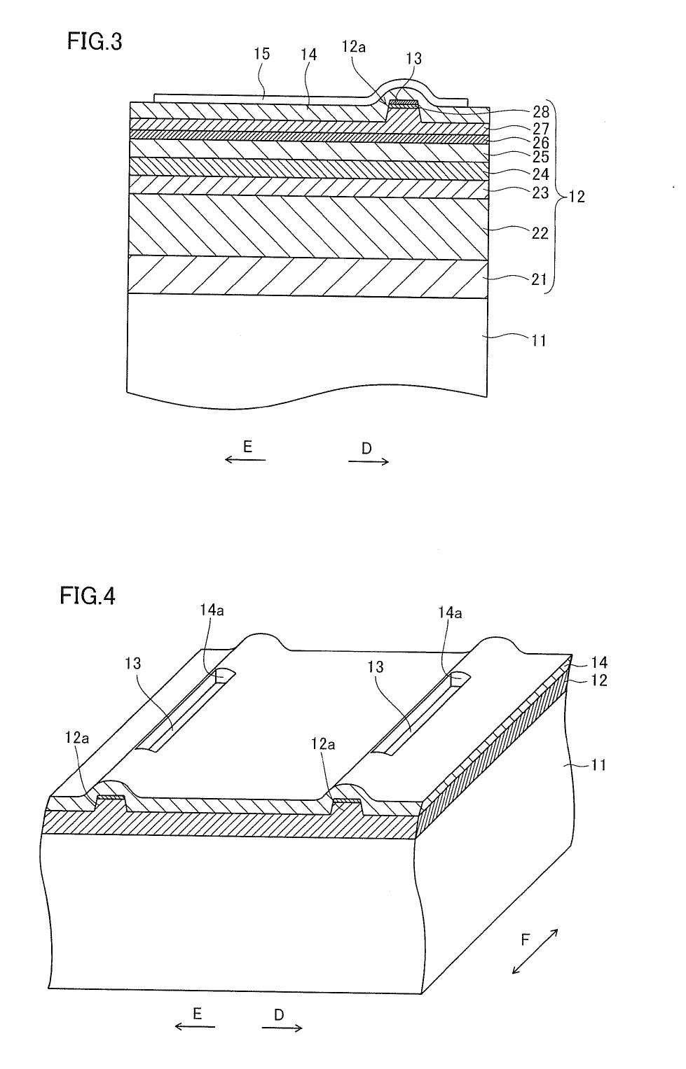

The structure of a GaN-based semiconductor laser chip according to a first embodiment is described with reference to FIGS. 2 and 3. In the first embodiment, the GaN-based semiconductor laser chip is described as an example of the semiconductor laser device according to the present invention. The GaN-based semiconductor laser chip according to the first embodiment is a 400 nm-band semiconductor laser chip (violet laser diode).

In the GaN-based semiconductor laser chip according to the first embodiment, a semiconductor layer 12 including an active layer 24 (see FIG. 3) described later and having a p-n junction is formed on an n-type GaN substrate 11, as shown in FIG. 2. This semiconductor layer 12 includes a ridge portion 12a constituting a waveguide extending in a direction F in a striped (slender) manner. The n-type GaN substrate 11 is an example of the “substrate” in the present invention. This GaN-based semiconductor laser chip is so formed that the length (width) along arrow D (along arrow E) is about 200 μm and the length (depth) in the direction F is about 400 μm. A cleavage direction (direction substantially orthogonal to the ridge portion 12a) (along arrow D (along arrow E)) is the <11-20> direction. A plane (cleavage plane 17 or 18 described later) emitting a laser beam is the M plane ({1-100} plane).

According to the first embodiment, the ridge portion 12a is formed on a region approaching a first side (along arrow D) by a distance W0 (=about 30 μm) from a center 100 of the GaN-based semiconductor laser chip (n-type GaN substrate 11) along arrow D (along arrow E), and formed inward by a prescribed distance W1 (=about 70 μm) from an end of the first side (along arrow D) of the GaN-based semiconductor laser chip (n-type GaN substrate 11). A p-side electrode 13 obtained by stacking a Pt film and Pd film successively from the side of the ridge portion 12a (lower side) is formed on the upper surface of this ridge portion 12a. A current blocking layer 14 consisting of an SiO₂ film having a thickness of about 300 nm is formed on the semiconductor layer 12, to cover the p-side electrode 13. An opening 14a is provided on a region of this current blocking layer 14 immediately above the p-side electrode 13 other than the vicinity of both ends (cleavage planes 17 and 18 described later) in the direction F. A p-side pad electrode 15 obtained by stacking a Ti film and an Au film successively from the side of the p-side electrode 13 and the current blocking layer 14 (lower side) is formed on regions of the p-side electrode 13 and the current blocking layer 14 enclosed with lines inward by about 30 μm from the end surfaces (four sides) of the GaN-based semiconductor laser chip (n-type GaN substrate 11). The p-side pad electrode 15 is an example of the “first electrode layer” in the present invention. This p-side pad electrode 15 is so formed that the length (width) along arrow D (along arrow E) is about 140 μm and the length (depth) in the direction F is about 340 μm. An n-side electrode 16 obtained by stacking a Ti film, a Pt film and an Au film successively from the side of the n-type GaN substrate 11 (upper side) is formed on the back surface of the GaN-based semiconductor laser chip (n-type GaN substrate 11). The n-side electrode 16 is an example of the “second electrode layer” in the present invention.

Two cleavage planes 17 and 18 are formed to be orthogonal to the ridge portion 12a constituting the waveguide. These two cleavage planes 17 and 18 constitute a cavity.

According to the first embodiment, cleavage introduction steps 19a and 19b for performing cleavage having a depth of about 20 μm are formed on the n-type GaN substrate 11, the semiconductor layer 12 and the current blocking layer 14 from the upper surface side of the GaN-based semiconductor laser chip. The cleavage introduction steps 19a and 19b are examples of the “first step” in the present invention. These cleavage introduction steps 19a and 19b are formed only on a region of a side (along arrow E) opposite to the first side (along arrow D) of the ridge portion 12a at a prescribed interval (at least about 70 μm) from the ridge portion 12a (waveguide) along the direction (along arrow D (along arrow E)) orthogonal to the ridge portion 12a (waveguide) respectively.

According to the first embodiment, the cleavage introduction steps 19a and 19b are so arranged that the centers of the cleavage introduction steps 19a and 19b along arrow D (along arrow E) are at a prescribed distance W2 (=about 100 μm) from the (waveguide) of the ridge portion 12a along arrow E, and at a prescribed distance W3 (=about 30 μm) from an end surface of the GaN-based semiconductor laser chip (n-type GaN substrate 11) along arrow E.

According to the first embodiment, the cleavage introduction steps 19a and 19b are formed on a region not provided with the p-side pad electrode 15.

According to the first embodiment, separation introduction steps 20a and 20b for performing separation are formed on ends of the n-type GaN substrate 11 and the n-side electrode 16 along arrow D and along arrow E from the back surface side of the GaN-based semiconductor laser chip along the extensional direction (direction F) of the ridge portion 12a (waveguide) respectively. The separation introduction steps 20a and 20b are examples of the “second step” in the present invention.

As to the detailed structures of the n-type GaN substrate 11 and the semiconductor layer 12, the n-type GaN substrate 11 is doped with oxygen, and consists of a hexagonal structure. The semiconductor layer 12 has a surface consisting of a C plane (plane orientation (0001)) of a Ga surface. The semiconductor layer 12 is arranged on the n-type GaN substrate 11, and provided with a buffer layer 21 consisting of a Si-doped n-type GaN layer, as shown in FIG. 3. An n-type cladding layer 22 of n-type Al_{0.05}Ga_{0.95}N is formed on this buffer layer 21.

An n-side optical guide layer 23 of undoped GaN is formed on the n-type cladding layer 22. An active layer 24 having a multiple quantum well (MQW) structure is formed on this n-side optical guide layer 23. This active layer 24 has a structure obtained by alternately stacking two barrier layers (not shown) of undoped GaN and three well layers (not shown) of undoped In_{0.1}Ga_{0.9}N.

A p-side optical guide layer 25 of undoped GaN is formed on the active layer 24. A cap layer 26 of undoped Al_{0.3}Ga_{0.7}N is formed on this p-side optical guide layer 25. This cap layer 26 has a function of suppressing deterioration of the crystal quality of the active layer 24 by suppressing desorption of 1n atoms of the active layer 24.

A p-type cladding layer 27, doped with Mg, of p-type Al_{0.05}Ga_{0.95}N is formed on the cap layer 26. This p-type cladding layer 27 has a projecting portion, formed by etching a prescribed region from the upper surface of the p-type cladding layer 27, having a width of about 1.5 μm and extending in the direction F (see FIG. 2). A p-side contact layer 28 of undoped In_{0.05}Ga_{0.95}N is formed on the projecting portion of the p-side cladding layer 27. The projecting portion of the p-type cladding layer 27 and the p-side contact layer 28 form the ridge portion 12a becoming a current injection region and constituting the waveguide.

A manufacturing process (wafer process) in a wafer state of the GaN-based semiconductor laser chip according to the first embodiment is described with reference to FIGS. 2 to 5.

First, the buffer layer 21 consisting of the Si-doped n-type GaN layer, the n-type cladding layer 22 of n-type Al_{0.05}Ga_{0.95}N and the n-side optical guide layer 23 of undoped GaN are successively grown on the n-type GaN substrate 11 by MOVPE (Metal Organic Vapor Phase Epitaxy) at a substrate temperature of about 1150° C., as shown in FIG. 3.

Thereafter the active layer 24 is formed by alternately growing the three well layers (not shown) of undoped In_{0.1}Ga_{0.9}N and the two barrier layers (not shown) of undoped GaN on the n-side optical guide layer 23 by MOVPE at a substrate temperature of about 850° C. Then, the p-side optical guide layer 25 of undoped GaN and the cap layer 26 of undoped Al_{0.3}Ga_{0.7}N are successively formed on the active layer 24.

Thereafter the p-type cladding layer 27, doped with Mg, of p-type Al_{0.05}Ga_{0.95}N is grown on the cap layer 26 by MOVPE at a substrate temperature of about 1150° C.

Then, the p-side contact layer 28 of undoped In_{0.05}Ga_{0.95}N is formed on the p-type cladding layer 27 by MOVPE at a substrate temperature of about 850° C.

Thereafter the ridge portion 12a and the p-side electrode 13 are formed by employing vacuum evaporation and etching. More specifically, the Pt film and the Pd film are formed on the p-side contact layer 28 by vacuum evaporation successively from the side of the p-side contact layer 28 (lower side). Then, etching is employed for etching the Pt film and the Pd film through a mask of photoresist (not shown) extending in the direction F (see FIG. 2), and etching the p-side contact layer 28 and a prescribed region from the upper surface of the p-type cladding layer 27. Thus, the ridge portion 12a having the width of about 1.5 μm constituted of the p-side contact layer 28 and the projecting portion of the p-type cladding layer 27 and the p-side electrode 13 arranged on the ridge portion 12a are formed. At this time, the ridge portion 12a is so formed as to extend in the direction (<1-100> direction) (direction F (see FIG. 2)) substantially orthogonal to the <11-20> direction (along arrow D (along arrow E)) which is the cleavage direction at an interval of about 200 μm. The ridge portion 12a has a function for serving as the current injection region and the waveguide. Thus, the semiconductor layer 12 consisting of the buffer layer 21, the n-type cladding layer 22, the n-side optical guide layer 23, the active layer 24, the p-side optical guide layer 25, the cap layer 26, the p-type cladding layer 27 and the p-side contact layer 28 is formed.

Thereafter the current blocking layer 14 consisting of the SiO₂ film having the thickness of about 300 nm is formed on the semiconductor layer 12 by plasma CVD to cover the p-side electrodes 13, as shown in FIG. 4.

Then, etching is employed for etching the current blocking layer 14 through a mask of photoresist (not shown), for forming openings 14a on portions of the current blocking layer 14 other than the vicinity of cleavage plane forming regions in the regions immediately above the p-side electrodes 13. Thus, the upper surfaces of the p-side electrodes 13 are exposed.

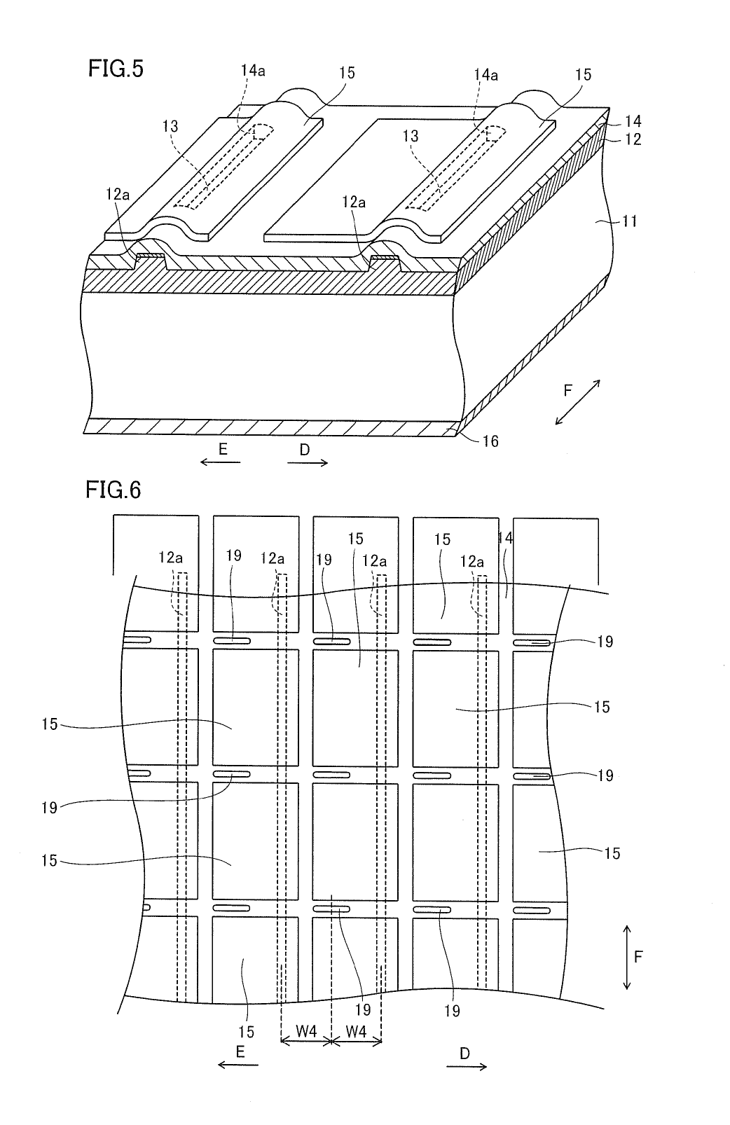

Thereafter p-side pad electrodes 15 are formed by stacking Ti films and Au films on prescribed regions of the p-side electrodes 13 and the current blocking layer 14 successively from the side of the p-side electrodes 13 and the current blocking layer 14 (lower side) by vacuum evaporation and a lift-off method, as shown in FIG. 5. More specifically, photoresist films (not shown) are formed on regions (regions up to about 30 μm from positions forming end surfaces) of the current blocking layer 14 other than regions enclosed with lines inward by about 30 μm from positions for forming the end surfaces (four sides) of the GaN-based semiconductor laser chip (n-type GaN substrate 11). Then, the Ti films and the Au films are formed on the p-side electrodes 13 and the current blocking layer 14 successively from the side of the p-side electrodes 13 and the current blocking layer 14 (lower side) by vacuum evaporation. Thereafter the photoresist films (not shown) are removed by the lift-off method, whereby the p-side pad electrodes 15 are formed on the regions (regions other than the regions up to about 30 μm from the positions forming the end surfaces) of the p-side electrodes 13 and the current blocking layer 14 enclosed with the lines inward by about 30 μm from the positions for forming the end surfaces (four sides) of the GaN-based semiconductor laser chip (n-type GaN substrate 11). At this time, the p-side pad electrodes 15 are arranged on regions where the centers of the p-side pad electrodes 15 along arrow D (along arrow E) approach a side (along arrow E) opposite to the first side (along arrow D) by about 30 μm from ridge portions 12a constituting waveguides. Each p-side pad electrode 15 is so formed that the length (width) along arrow D (along arrow E) is about 140 μm and the length (depth) in the direction F is about 340 μm.

Then, the back surface side of the n-type GaN substrate 11 is polished until the thickness of the n-type GaN substrate 11 reaches about 100 μm, for example.

Thereafter the n-side electrode 16 is formed on the back surface of the n-type GaN substrate 11 by stacking the Ti film, the Pt film and the Au film successively from the side of the n-type GaN substrate 11 (upper side) by vacuum evaporation.

A wafer having GaN-based semiconductor laser chips arranged in the form of a matrix is completed in the aforementioned manner.

A manufacturing process (singulation step) subsequent to the wafer process for the GaN-based semiconductor laser chip according to the first embodiment is described with reference to FIGS. 2 and 6 to 9.

First, first cleavage introduction recess portions 19 extending in the direction (along arrow D and along arrow E) orthogonal to the ridge portions 12a are formed at intervals of about 400 μm along the extensional direction (direction F) of the striped ridge portions 12a from the side of the semiconductor layer 12 (upper side) with a diamond point or a laser beam, as shown in FIG. 6. At this time, the first cleavage introduction recess portions 19 are formed on regions not provided with the p-side pad electrodes 15, whereby development of metal swarfs or the like can be suppressed when forming the same with the diamond point or the laser beam. Thus, the p-side layers (the p-type cladding layer 27, the p-side contact layer 28, the p-side electrodes 13 and the p-side pad electrodes 15) and the n-side layers (the n-side electrode 16, the n-type GaN substrate 11, the buffer layer 21 and the n-type cladding layer 22) can be inhibited from electrically short-circuiting by metal swarfs or the like.

According to the first embodiment, the first cleavage introduction recess portions 19 are not formed on regions of about 70 μm from the ridge portions 12a formed every interval of about 200 μm along arrow D (along arrow E) but the centers of the cleavage introduction recess portions 19 along arrow D (along arrow E) are formed at prescribed intervals W4 (=about 100 μm) from the adjacent ridge portions 12a (waveguides). In other words, the first cleavage introduction recess portions 19 are so formed that the centers of the first cleavage introduction recess portions 19 along arrow D (along arrow E) are arranged on intermediate positions between the adjacent ridge portions 12a (waveguides). Thus, reduction of the distance between the first cleavage introduction recess portions 19 and the ridge portions 12a can be suppressed, whereby damage of the ridge portions 12a can be suppressed when forming the first cleavage introduction recess portions 19. Further, the first cleavage introduction recess portions 19 are so formed as to have a depth of about 20 μm, and formed on the n-type GaN substrate 11, the semiconductor layer 12 and the current blocking layer 14 from the upper surface side of the GaN-based semiconductor laser chip. In the state before the wafer is cleaved, the first cleavage introduction recess portions 19 are in the form of grooves.

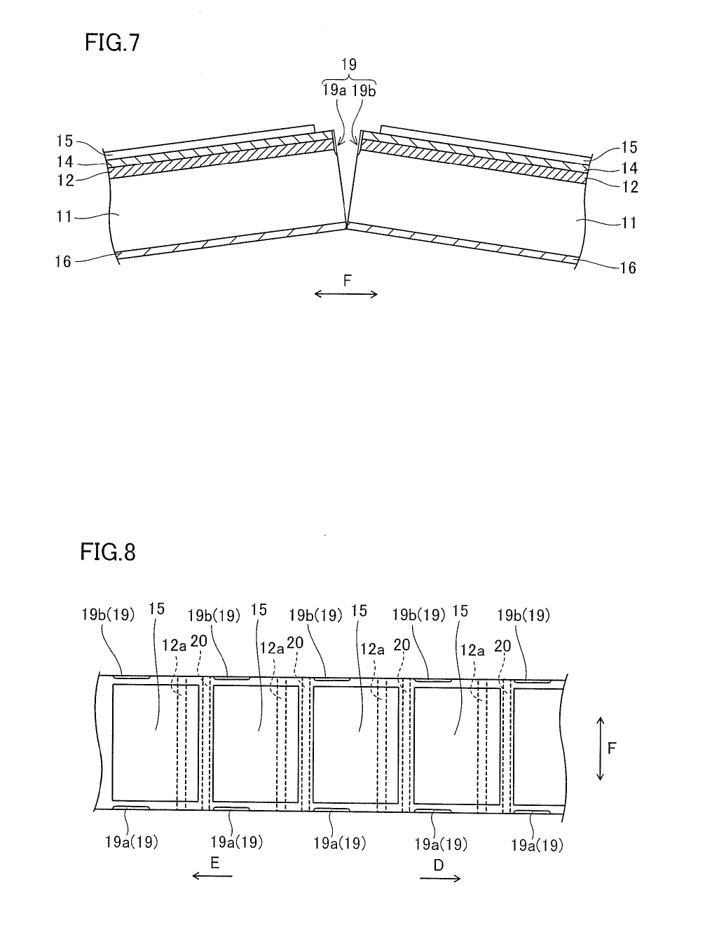

In this state, the wafer is cleaved on the position of each first cleavage introduction recess portion 19 along arrow D (along arrow E) (see FIG. 6) by applying a load while fulcruming the lower side of the n-type GaN substrate 11 so that the upper side of the wafer opens, as shown in FIG. 7. Thus, the wafer is formed into a bar having GaN-based semiconductor laser chips aligned with each other along arrow D (along arrow E), as shown in FIG. 8. At this time, the wafer is cleaved while fulcruming the lower side of the n-type GaN substrate 11 so that the upper side opens, whereby application of the load to the ridge portions 12a of the semiconductor layer 12 can be suppressed. Thus, mechanical damage of the ridge portions 12a of the semiconductor layer 12 can be suppressed, whereby deterioration of the laser characteristics can be suppressed.

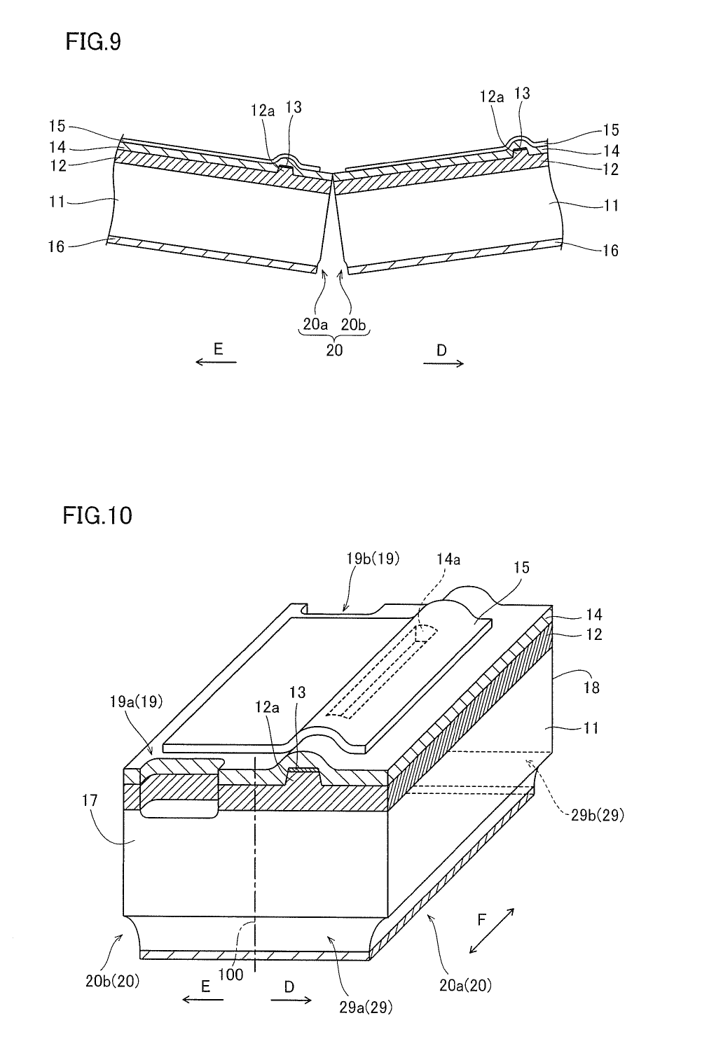

Then, separation introduction recess portions 20 are formed at intervals of about 200 μm in the extensional direction (direction F) (see FIG. 8) of the striped ridge portions 12a from the back surface side of the n-type GaN substrate 11 of the wafer cleaved in the form of a bar with the diamond point or the laser beam, as shown in FIGS. 8 and 9. At this time, the separation introduction recess portions 20 are formed on positions separated from the ridge portions 12a by about 70 μm along arrow D, and formed on positions separated from the ridge portions 12a by about 130 μm along arrow E. Further, the separation introduction recess portions 20 are formed on the n-type GaN substrate 11 and the n-side electrode 16 from the back surface side of the GaN-based semiconductor laser chip. Thus, the separation introduction recess portions 20 can be formed at a prescribed distance from the ridge portions 12a in the thickness direction (vertical direction) also when the ridge portions 12a are so arranged as to approach the side of the GaN-based semiconductor laser chip along arrow D, whereby damage of the ridge portions 12a can be suppressed when forming the separation introduction recess portions 20. In the state before the wafer cleaved in the form of a bar is separated, the separation introduction recess portions 20 are in the form of grooves.

In this state, the bar-shaped wafer is separated on the position of each separation introduction recess portion 20 along arrow F (see FIG. 8) by applying a load while fulcruming the side of the semiconductor layer 12 (upper side) so that the lower side of the GaN-based semiconductor laser chip opens, as shown in FIG. 9. Thus, the bar-shaped wafer is separated into the GaN-based semiconductor laser chip having the length (width) of about 200 μm along arrow D (along arrow E) and the length (depth) of about 400 μm in the direction F as shown in FIG. 2, and a large number of GaN-based semiconductor laser chips are manufactured.

According to the first embodiment, as hereinabove described, the ridge portion 12a constituting the waveguide extending in the direction in the striped (slender) manner is formed on the region approaching the first side (along arrow D) by the distance W0 (=about 30 μm) from the center of the semiconductor layer 12 along arrow D (along arrow E) so that bonding of a metal wire onto the ridge portion 12a constituting the waveguide can be suppressed in a case of bonding the metal wire to the center of the upper surface side of the semiconductor layer 12 for supplying power to the upper surface side of the semiconductor layer 12, whereby damage of the ridge portion 12a constituting the waveguide can be suppressed in bonding. Thus, deterioration of the laser characteristics can be suppressed. Further, the cleavage introduction steps 19a and 19b (first cleavage introduction recess portions 19) are formed on the region of the side (along arrow E) opposite to the first side of the ridge portion 12a from the side of the semiconductor layer 12 (upper side) so that the cleavage introduction steps 19a and 19b (first cleavage introduction recess portions 19) can be formed on the positions separated from the ridge portion 12a constituting the waveguide, whereby damage of the ridge portion 12a constituting the waveguide can be suppressed when forming the cleavage introduction steps 19a and 19b (first cleavage introduction recess portions 19) from the side of the semiconductor layer 12 (upper side). Deterioration of the laser characteristics can be suppressed also by this.

According to the first embodiment, the cleavage introduction steps 19a and 19b are formed from the side of the semiconductor layer 12 up to the depth reaching the n-type GaN substrate 11, whereby not only the semiconductor layer 12 but also the n-type GaN substrate 11 can be easily cleaved when forming cavity facets (cleavage planes 17 and 18) by cleavage.

According to the first embodiment, the cleavage introduction steps 19a and 19b are so formed that the width in the direction intersecting with the prescribed extensional direction (direction F) of the ridge portion 12a (waveguide) is increased upward so that energy for forming ends of the cleavage introduction steps 19a and 19b by laser application or the like can be reduced below energy for forming the bottoms of the cleavage introduction steps 19a and 19b by laser application or the like, whereby a bad influence on the ridge portion 12a (waveguide) close to the ends of the cleavage introduction steps 19a and 19b can be suppressed, and deterioration of the ridge portion 12a (waveguide) can be suppressed.

According to the first embodiment, the GaN-based semiconductor laser chip comprises the p-side pad electrode 15 formed on the semiconductor layer 12 and the p-side pad electrode 15 is formed at the prescribed interval (about 30 μm) from the cleavage introduction steps 19a and 19b so that the p-side pad electrode 15 and the cleavage introduction steps 19a and 19b are formed at the prescribed interval, whereby a leakage current can be inhibited from increase resulting from adhesion of the material forming the p-side pad electrode 15 to the portions of the cleavage introduction steps 19a and 19b also when a conductive material constituting the p-side pad electrode 15 scatters.

According to the first embodiment, the separation introduction steps 20a and 20b are so formed as to have the length substantially identical to the length between the cleavage planes 17 and 18 of the ridge portion 12a (waveguide), whereby separation can be reliably performed in the extensional direction (direction F) of the separation introduction steps 20a and 20a when forming the GaN-based semiconductor laser chip by separation.

According to the first embodiment, the separation introductions steps 20a and 20b are so formed as to have the depth reaching parts of the lower surface of the n-type GaN substrate 11 from the side of the n-side electrode 16, whereby separation in formation of the GaN-based semiconductor laser chip can be easily performed through the separation introduction steps 20a and 20b.

### First Modification of First Embodiment

In this GaN-based semiconductor laser chip according to a first modification of the first embodiment, cleavage introduction steps 29a and 29b (second cleavage introduction recess portions 29) are formed also from a lower surface side (side of an n-type GaN substrate 11) in addition to cleavage introduction steps 19a and 19b formed from an upper surface side (side of a semiconductor layer 12) of the GaN-based semiconductor laser chip as shown in FIG. 10, dissimilarly to the aforementioned first embodiment. The cleavage introduction steps 29a and 29b are examples of the “third step” in the present invention. In particular, these cleavage introduction steps 29a and 29b are formed on the overall regions of cleavage planes 17 and 18 along a direction (along arrow D (along arrow E)) orthogonal to a ridge portion 12a (waveguide) respectively. According to this structure, a wafer can be more easily cleaved in the form of a bar in a manufacturing process (singulation process).

### Second Modification of First Embodiment

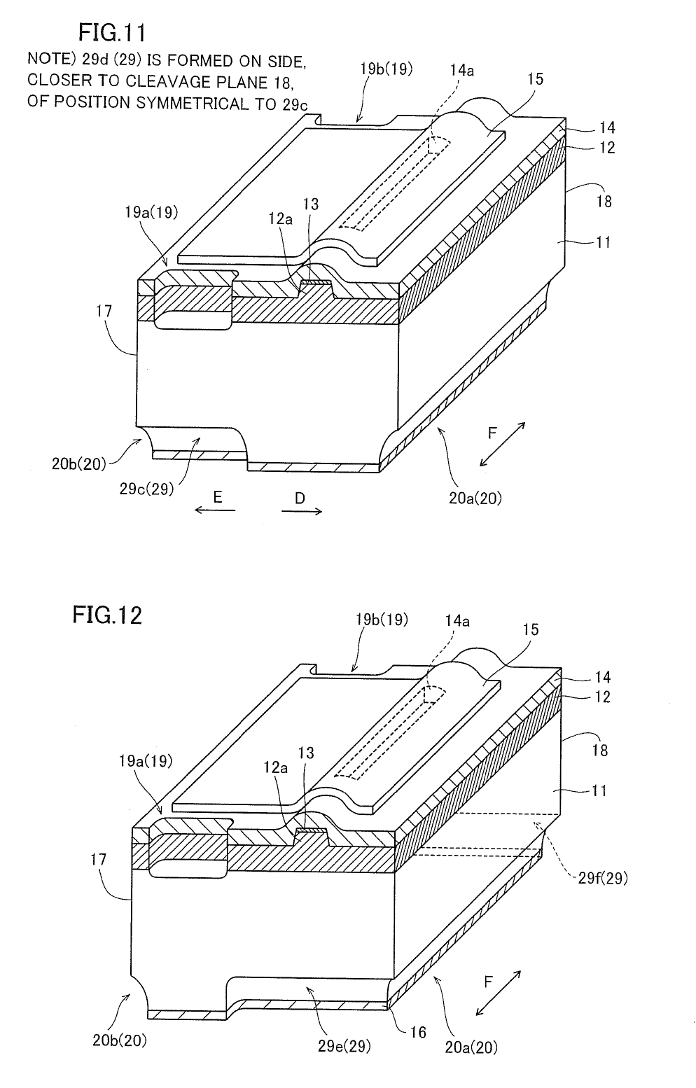

In this GaN-based semiconductor laser chip according to a second modification of the first embodiment, cleavage introduction steps 29c and 29d (second cleavage introduction recess portions 29) are formed only on a partial region substantially opposite to cleavage introduction steps 19a and 19b and not formed on a region opposed to a ridge portion 12a (waveguide) as shown in FIG. 11, dissimilarly to the first modification of the aforementioned first embodiment. The cleavage introduction steps 29c and 29d are examples of the “third step” in the present invention. According to this structure, an impact following scribing can be inhibited from influencing the ridge portion 12a (waveguide) in a case of providing the cleavage introduction recess portions 29 with a diamond point in a state thinly forming an n-type GaN substrate 11, for example, in addition to effects similar to those of the first modification of the aforementioned first embodiment. According to the aforementioned structure, further, the cleavage introduction recess portions 29 may not be provided on the overall regions of cleavage planes 17 and 18 along a direction (along arrow D (along arrow E)) orthogonal to the ridge portion 12a in a case of providing the cleavage introduction recess portions 29 with the diamond point, for example, whereby abrasion of the diamond point can be suppressed.

### Third Modification of First Embodiment

In this GaN-based semiconductor laser chip according to a third modification of the first embodiment, cleavage introduction steps 29e and 29f (second cleavage introduction recess portions 29) are formed only on positions substantially opposite to a ridge portion 12a (waveguide) and not formed on positions opposite to cleavage introduction steps 19a and 19b formed on an upper surface side of the GaN-based semiconductor laser chip as shown in FIG. 12, dissimilarly to the second modification of the aforementioned first embodiment. The cleavage introduction steps 29e and 29f are examples of the “third step” in the present invention. According to this structure, the second cleavage introduction recess portions 29 may not be provided on the overall regions of cleavage planes 17 and 18 along a direction (along arrow D (along arrow E)) orthogonal to the ridge portion 12a in a case of providing the second cleavage introduction recess portions 29 with a diamond point, for example, whereby abrasion of the diamond point can be suppressed. Further, cleavage introduction steps 29a and 29b and the cleavage introduction steps 29e and 29f are alternately provided on the upper surface side and the lower surface side of the GaN-based semiconductor laser chip respectively, whereby a wafer can be more easily cleaved in the form of a bar in a manufacturing process (singulation process).

### Fourth Modification of First Embodiment

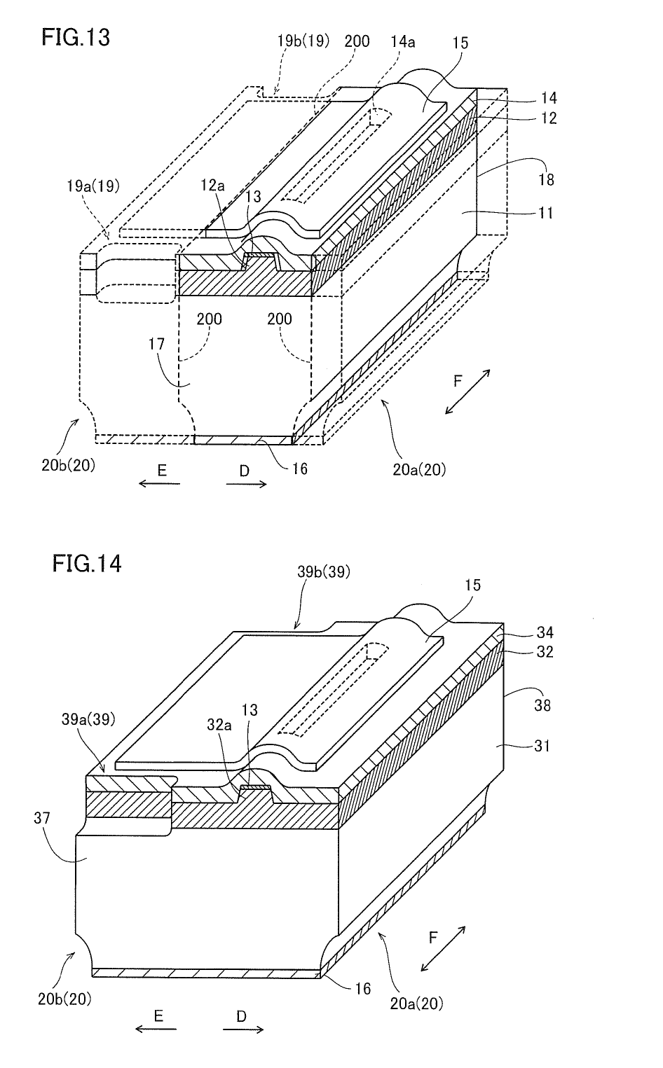

In this GaN-based semiconductor laser chip according to a fourth modification of the first embodiment, a bar-shaped wafer is separated along a parting line 200 (broken line) along an extensional direction (along arrow F) of a ridge portion 12a on a position of about 40 μm from the ridge portion 12a along arrow D and a position of about 100 μm from the ridge portion 12a along arrow E respectively as shown in FIG. 13, dissimilarly to the aforementioned first embodiment. Referring to FIG. 13, a part shown by solid lines corresponds to the separated GaN-based semiconductor laser chip. According to this structure, separation can be so performed as to deviate the ridge portion 12a by about 30 μm from the center of the GaN-based semiconductor laser chip and to completely remove cleavage introduction steps 19a and 19b (first cleavage introduction recess portions 19) (shown by broken lines) from the GaN-based semiconductor laser chip. Thus, development of a leakage current through the cleavage introduction steps 19a and 19b can be suppressed, whereby reliability of the laser device can be more improved.

### Second Embodiment

Referring to FIG. 14, a case of forming cleavage introduction steps up to an end of a GaN-based semiconductor laser chip dissimilarly to the aforementioned first embodiment is described in this second embodiment.

In this GaN-based semiconductor laser chip according to the second embodiment, a semiconductor layer 32 including a ridge portion 32a constituting a waveguide extending in a direction F in a striped (slender) manner is formed on an n-type GaN substrate 31 as shown in FIG. 14, similarly to the aforementioned first embodiment. The n-type GaN substrate 31 is an example of the “substrate” in the present invention. A current blocking layer 34 consisting of an SiO₂ film having a thickness of about 300 nm is formed on the semiconductor layer 32, to cover a p-side electrode 13. Two cleavage planes 37 and 38 constituting a cavity are formed to be orthogonal to the ridge portion 32a constituting the waveguide.

According to the second embodiment, cleavage introduction steps 39a and 39b having a length of about 60 μm along arrow D (along arrow E) are formed on the n-type GaN substrate 31, the semiconductor layer 32 and the current blocking layer 34 to extend up to an end of the GaN-based semiconductor laser chip along arrow E, dissimilarly to the aforementioned first embodiment. The cleavage introduction steps 39a and 39b are examples of the “first step” in the present invention.

The remaining structure of the second embodiment is similar to the aforementioned first embodiment.

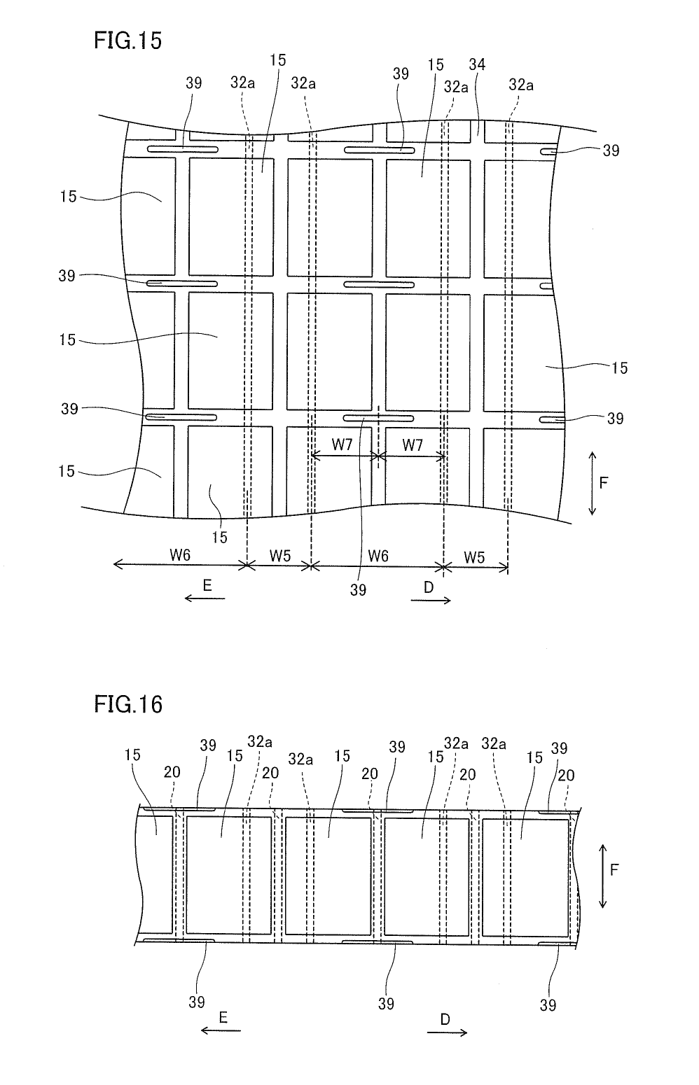

A manufacturing process (wafer process) in a wafer state of the GaN-based semiconductor laser chip according to the second embodiment is described with reference to FIGS. 14 and 15.

First, the layers up to a p-side contact layer (not shown) are formed on the n-type GaN substrate 31 through a process similar to the aforementioned first embodiment, as shown in FIG. 14. Thereafter the ridge portion 32a and the p-side electrode 13 are formed by vacuum evaporation and etching.

At this time, a plurality of ridge portions 32a are so formed as to alternately have two different intervals, i.e., prescribed intervals W5 (=about 140 μm) and W6 (=about 260 μm) according to the second embodiment, as shown in FIG. 15.

Thereafter each p-side pad electrode 15 is formed on regions (regions other than regions up to about 30 μm from positions forming end surfaces) of the p-side electrode 13 (see FIG. 14) and the current blocking layer 34 enclosed with lines inward by about 30 μm from the positions forming the end surfaces (four sides) of the GaN-based semiconductor laser chip (n-type GaN substrate 31) as shown in FIGS. 14 and 15, through a process similar to the aforementioned first embodiment. At this time, the p-side pad electrode 15 is arranged on a region where the center of the p-side pad electrode 15 along arrow D (along arrow E) approaches the side along arrow D or along arrow E by about 30 μm from the ridge portion 32a constituting the waveguide according to the second embodiment.

Another manufacturing process (wafer process) in the wafer state according to the second embodiment is similar to the manufacturing process in the wafer state according to the aforementioned first embodiment.

A manufacturing process (singulation process) subsequent to the wafer process for the GaN-based semiconductor laser chip according to the second embodiment is described with reference to FIGS. 14 to 16.

First, first cleavage introduction recess portions 39 extending in the direction (along arrow D and along arrow E) orthogonal to ridge portions 32a are formed along the extensional direction (direction F) of the striped ridge portions 32a at intervals of about 400 μm from the side of the wafer closer to the semiconductor layer 32 (upper side) with a diamond point or a laser beam through a process similar to the aforementioned first embodiment, as shown in FIG. 15.

At this time, the first cleavage introduction recess portions 39 having a length of about 120 μm are formed only between the ridge portions 32a (waveguides) having the larger interval W6 (=about 260 μm) in the two different intervals, according to the second embodiment. In a state before the wafer is cleaved, the first cleavage introduction recess portions 39 are in the form of grooves.

According to the second embodiment, the first cleavage introduction recess portions 39 are not formed on regions of about 70 μm from the adjacent ridge portions 32a, but the centers of the first cleavage introduction recess portions 39 along arrow D (along arrow E) are formed at prescribed distances W7 (=about 130 μm) from the adjacent ridge portions 32a (waveguides). In other words, the first cleavage introduction recess portions 39 are so formed that the centers of the first cleavage introduction recess portions 39 along arrow D (along arrow E) are arranged on intermediate positions between the adjacent ridge portions 32a (waveguides) having the interval W6 of about 260 μm.

In this state, the wafer is formed into a bar having GaN-based semiconductor laser chips aligned with each other along arrow D (along arrow E) as shown in FIG. 16, through a process similar to the aforementioned first embodiment.

Then, separation introduction recess portions 20 are formed from the back surface side of the n-type GaN substrate 31 (see FIG. 14) of the wafer cleaved in the form of a bar at intervals of about 200 μm in the extensional direction (direction F) of the striped ridge portions 32a, through a process similar to the aforementioned first embodiment.

At this time, the separation introduction recess portions 20 are formed on respective intermediate positions between the ridge portions 32a (waveguides) having the interval W5 (see FIG. 15) of about 140 μm and between the ridge portions 32a (waveguides) having the interval W6 (see FIG. 15) of about 260 μm, according to the second embodiment. In a state before the wafer cleaved in the form of a bar is separated, the separation introduction recess portions 20 are in the form of grooves.

The remaining manufacturing process (singulation process) subsequent to the wafer process in the second embodiment is similar to the manufacturing process subsequent to the wafer process in the aforementioned first embodiment.

According to the second embodiment, as hereinabove described, the ridge portion 32a can be easily so arranged as to approach a first side of the GaN-based semiconductor laser chip (n-type GaN substrate 31) by forming the plurality of ridge portions 32a (waveguides) to alternately have the two different intervals while forming the separation introduction recess portions 20 only between the adjacent ridge portions 32a (waveguides) having the larger interval W6 (=about 260 μm) in the two different intervals and performing separation on the intermediate positions between the ridge portions 32a (waveguides). Further, the number of the separation introduction recess portions 20 formed on the wafer can be reduced to half as compared with the aforementioned first embodiment by forming the separation introduction recess portions 20 only between the adjacent ridge portions 32a (waveguides) having the larger interval W6 (=about 260 μm) in the two different intervals and performing separation on the intermediate positions between the ridge portions 32a (waveguides), whereby the time for forming the separation introduction recess portions 20 can be reduced.

The remaining effects of the second embodiment are similar to the aforementioned first embodiment.

### Third Embodiment

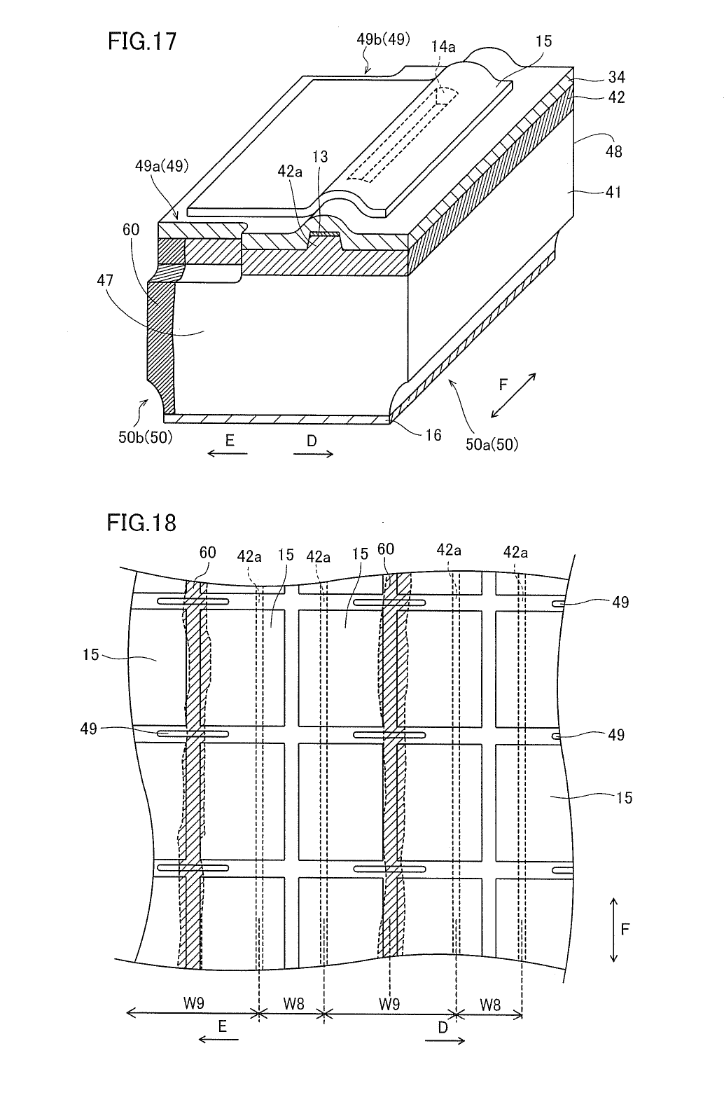

Referring to FIG. 17, a case of forming a GaN-based semiconductor laser chip with an n-type GaN substrate having a region including a large number of crystal defects dissimilarly to the aforementioned second embodiment is described in this third embodiment. The n-type GaN substrate employed in the third embodiment is a substrate linearly concentrically forming crystal defects on a prescribed region thereby reducing the number of crystal defects in the remaining wide regions.

In this GaN-based semiconductor laser chip according to the third embodiment, a semiconductor layer 42 including a ridge portion 42a constituting a waveguide extending in a direction F in a striped (slender) manner is formed on an n-type GaN substrate 41 as shown in FIG. 17, similarly to the aforementioned second embodiment. The n-type GaN substrate 41 is an example of the “substrate” in the present invention.

According to the third embodiment, a region 60 having a large number of crystal defects is formed in the vicinity of ends of the n-type GaN substrate 41 and the semiconductor layer 42 along arrow E.

Two cleavage planes 47 and 48 constituting a cavity are formed to be orthogonal to the ridge portion 42a constituting the waveguide.

Cleavage introduction steps 49a and 49b having a length of about 60 μm along arrow D (along arrow E) are formed on the n-type GaN substrate 41, the semiconductor layer 42 and a current blocking layer 34 to extend up to an end of the GaN-based semiconductor laser chip along arrow E, similarly to the aforementioned second embodiment. The cleavage introduction steps 49a and 49b are examples of the “first step” in the present invention.

According to the third embodiment, separation introduction steps 50a and 50b for performing separation are formed on the n-type GaN substrate 41 and an n-side electrode 16 from the back surface side of the GaN-based semiconductor laser chip along the extensional direction (direction F) of the ridge portion 42a constituting the waveguide respectively, similarly to the aforementioned second embodiment. The separation introduction steps 50a and 50b are examples of the “second step” in the present invention.

The remaining structure of the third embodiment is similar to the aforementioned second embodiment.

A manufacturing process (wafer process) in a wafer state of the GaN-based semiconductor laser chip according to the third embodiment is described with reference to FIGS. 17 and 18.

First, the layers up to a p-side contact layer (not shown) are formed on the n-type GaN substrate 41 through a process similar to the aforementioned second embodiment, as shown in FIG. 17. At this time, a region of the semiconductor layer 42 formed on the region 60 of the n-type GaN substrate 41 having a large number of crystal defects also defines the region 60 having a large number of crystal defects, according to the third embodiment.

Then, the ridge portion 42a and a p-side electrode 13 are formed through a process similar to the aforementioned second embodiment. At this time, a plurality of ridge portions 42a are so formed as to alternately have two different intervals, i.e., prescribed intervals W8 (=about 140 μm) and W9 (=about 260 μm) as shown in FIG. 18, similarly to the aforementioned second embodiment.

According to the third embodiment, the ridge portions 42a (waveguides) are so formed that regions 60, having large numbers of crystal defects, of the n-type GaN substrate 41 and the semiconductor layer 42 are arranged on intermediate positions between the ridge portions 42a (waveguides) having the larger interval W9 (=about 260 μm) in the two different intervals.

The remaining manufacturing process (wafer process) in the wafer state according to the third embodiment is similar to the manufacturing process in the wafer state according to the aforementioned second embodiment.

A manufacturing process (singulation process) subsequent to the wafer process for the GaN-based semiconductor laser chip according to the third embodiment is described with reference to FIGS. 17 to 19.

First, first cleavage introduction recess portions 49 extending in the direction (along arrow D and along arrow E) orthogonal to the ridge portions 42a are formed along the extensional direction (direction F) of the striped ridge portions 42a at intervals of about 400 μm from the side of the wafer closer to the semiconductor layer 42 (upper side) with a diamond point or a laser beam through a process similar to the aforementioned second embodiment, as shown in FIG. 18. In a state before the wafer is cleaved, the first cleavage introduction recess portions 49 are in the form of grooves.

At this time, the first cleavage introduction recess portions 49 are so formed that the centers of the first cleavage introduction recess portions 49 along arrow D (along arrow E) are arranged at the centers of the regions 60, having large numbers of crystal defects, of the n-type GaN substrate 41 and the semiconductor layer 42, according to the third embodiment.

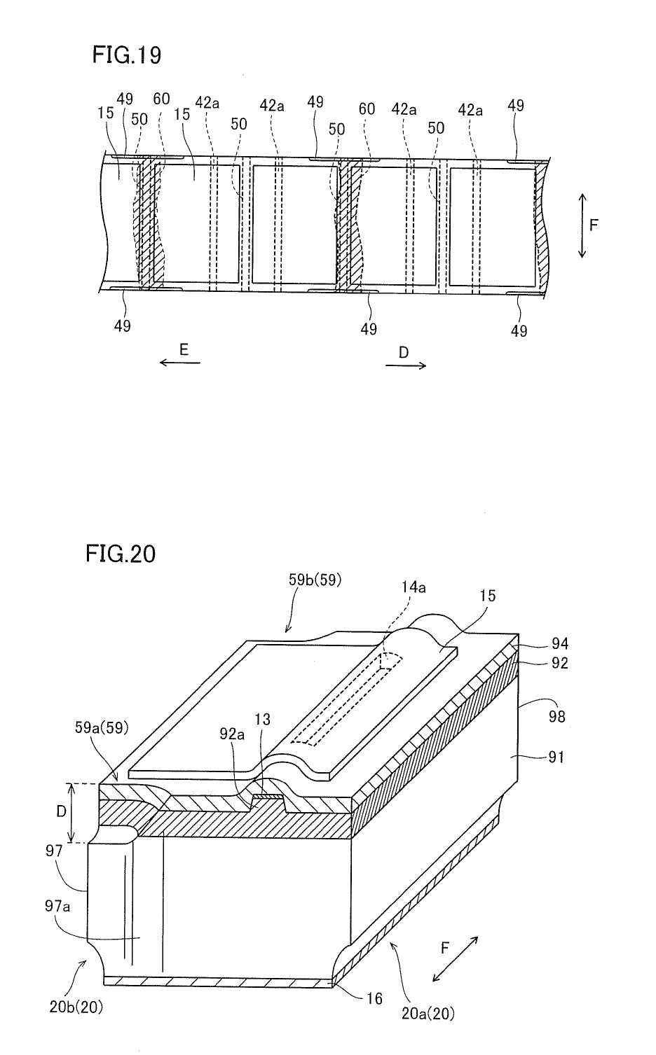

In this state, the wafer is formed into a bar having GaN-based semiconductor laser chips aligned with each other along arrow D (along arrow E) as shown in FIG. 19 through a process similar to the aforementioned second embodiment. In this case, the regions 60, having large numbers of crystal defects, provided substantially parallel to the ridge portions 42a are mechanically fragile as compared with the remaining regions, and tend to easily crack in the extensional direction of the regions 60. However, the first cleavage introduction recess portions 49 are substantially orthogonally formed across the regions 60, whereby the wafer can be precisely cleaved along the first cleavage introduction recess portions 49 to be formed into the bar.

Then, separation introduction recess portions 50 are formed from the back surface side of the n-type GaN substrate 41 (see FIG. 17) of the wafer cleaved in the form of a bar at intervals of about 200 μm in the extensional direction (direction F) of the striped ridge portions 42a through a process similar to the aforementioned second embodiment.

At this time, the separation introduction recess portions 50 are formed on respective intermediate positions between the ridge portions 42a (waveguides) having the interval W8 (see FIG. 18) of about 140 μm and between the ridge portions 42a (waveguides) having the interval W9 (see FIG. 18) of about 260 μm, according to the third embodiment. In a state before the wafer cleaved in the form of a bar is separated, the separation introduction recess portions 50 are in the form of grooves.

The remaining manufacturing process (singulation process) subsequent to the wafer process in the third embodiment is similar to the manufacturing process subsequent to the wafer process in the aforementioned second embodiment.

According to the third embodiment, as hereinabove described, the plurality of ridge portions 42a (waveguides) are so formed that the regions 60, having large numbers of crystal defects, of the n-type GaN substrate 41 and the semiconductor layer 42 are located on the intermediate positions between the adjacent ridge portions 42a (waveguides) having the larger interval W9 (=about 260 μm) in the two different intervals so that the ridge portions 42a (waveguides) can be formed on positions separated from the regions 60, having large numbers of crystal defects, of the n-type GaN substrate 41 and the semiconductor layer 42, whereby crystal defects of the n-type GaN substrate 41 and the semiconductor layer 42 can be inhibited from propagating to the ridge portions 42a (waveguides). Thus, reduction in reliability of the GaN-based semiconductor laser chip can be suppressed.

The remaining effects of the third embodiment are similar to the aforementioned second embodiment.

### Fourth Embodiment

Referring to FIGS. 20 to 22, a case of forming first cleavage introduction recess portions (cleavage introduction steps) having a substantially trapezoidal or substantially triangular sectional shape as viewed from the sides of cleavage planes in a manufacturing process (singulation process) subsequent to a wafer process for a GaN-based semiconductor laser chip dissimilarly to the aforementioned second embodiment is described in this fourth embodiment.

In this GaN-based semiconductor laser chip according to the fourth embodiment, a semiconductor layer 92 including a ridge portion 92a (waveguide) extending in a direction F in a striped (slender) manner is formed on an n-type GaN substrate 91 as shown in FIG. 20, similarly to the aforementioned second embodiment. The n-type GaN substrate 91 is an example of the “substrate” in the present invention. A current blocking layer 94 consisting of an SiO₂ film having a thickness of about 300 nm is formed on the semiconductor layer 92, to cover a p-side electrode 13. Two cleavage planes 97 and 98 constituting a cavity are formed to be orthogonal to the ridge portion 92a constituting the waveguide.

According to the fourth embodiment, cleavage introduction steps 59a and 59b (first cleavage introduction recess portions 59) having a depth of about 50 μm and having a substantially trapezoidal sectional shape as viewed from the sides of the cleavage planes 97 and 98 are formed on the upper surface side of the GaN-based semiconductor laser chip. In other words, the cleavage introduction steps 59a and 59b are so formed that inner side surfaces are directed toward an obliquely downward direction from the side of the semiconductor layer 92, and so formed as to have planar bottoms on positions (depth) reaching the n-type GaN substrate 91, as shown in FIG. 20. The cleavage introduction steps 59a and 59b are examples of the “first step” in the present invention.

As shown in FIG. 22, the cleavage introduction steps 59a and 59b are formed also in the extensional direction (direction F) of the ridge portion 92a in plan view, in shapes having steps 97a and 98a on parts of the cleavage planes 97 and 98.

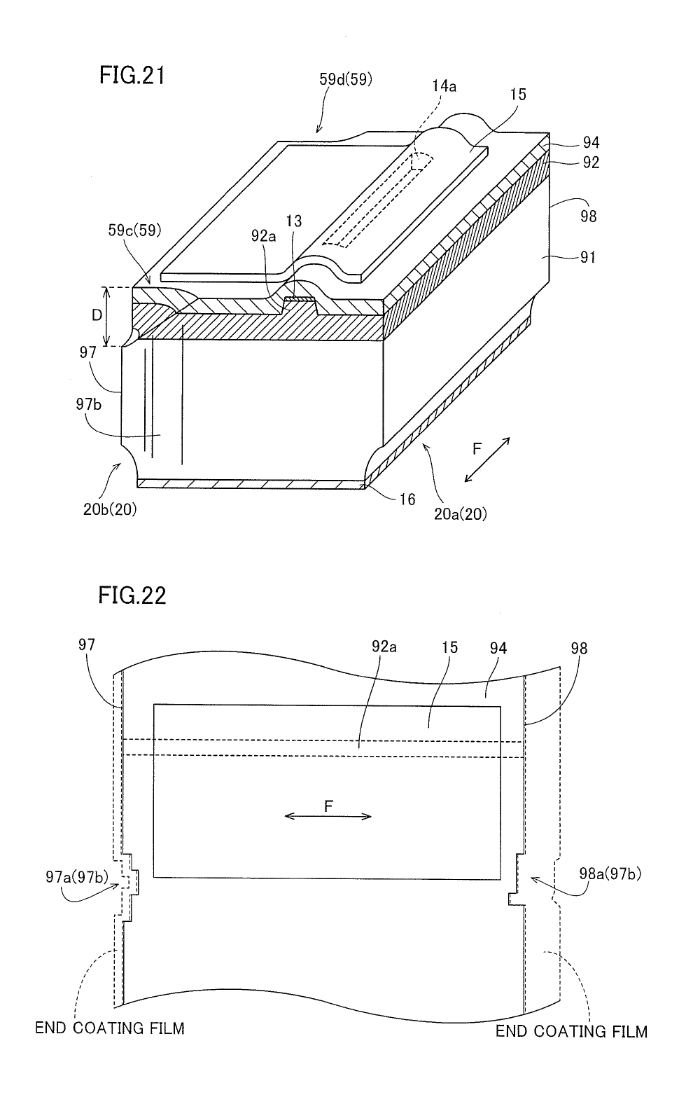

As shown in FIG. 21, cleavage introduction steps 59c and 59d (first cleavage introduction recess portions 59) having a depth of about 50 μm and having a substantially triangular sectional shape as viewed from the sides of the cleavage planes 97 and 98 are formed on the upper surface side of the GaN-based semiconductor laser chip. In other words, the cleavage introduction steps 59a and 59b are so formed as to have inclined surface portions whose inner side surfaces are directed toward an obliquely downward direction from the side of the semiconductor layer 92 and whose depth monotonically changes up to the deepest portions (reaching the n-type GaN substrate 91), as shown in FIG. 21. Also in plan view, the cleavage introduction steps 59c and 59d are so formed as to have steps 97b and 98b (see FIG. 22) on parts of the cleavage planes 97 and 98. The cleavage introduction steps 59c and 59d are examples of the “first step” in the present invention.

The remaining structure of the fourth embodiment is similar to the aforementioned second embodiment. Manufacturing processes (a wafer process and a singulation process) for the GaN-based semiconductor laser chip according to the fourth embodiment are similar to the manufacturing processes of the aforementioned second embodiment.

Effects resulting from the manufacturing processes for the GaN-based semiconductor laser chip according to the fourth embodiment are described with reference to FIGS. 20 to 23.

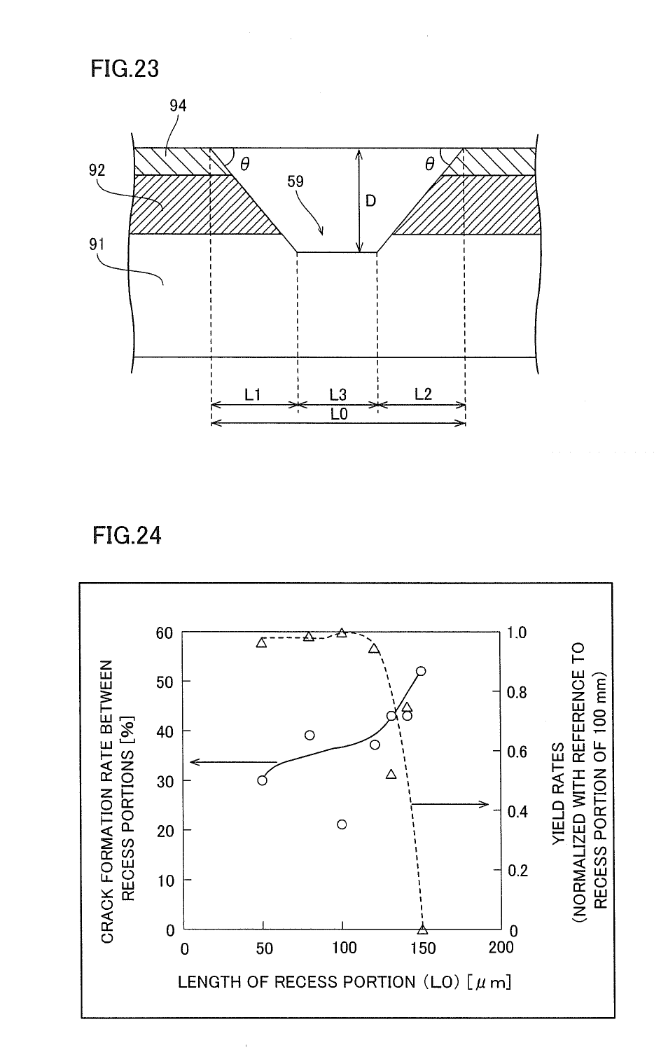

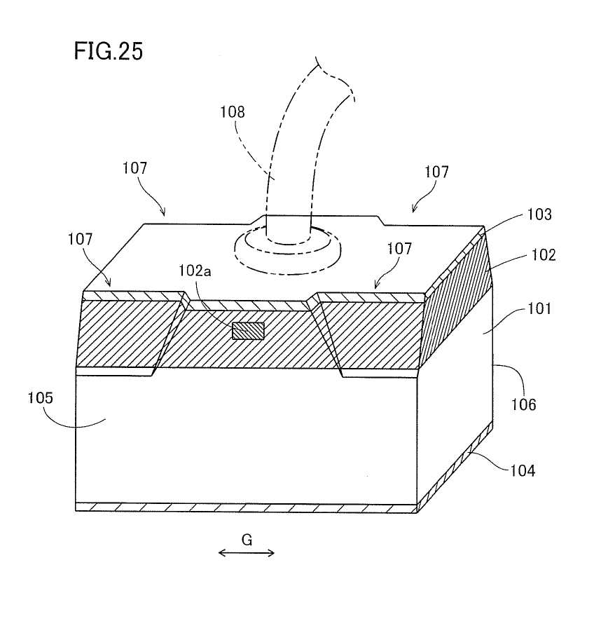

First, a first cleavage introduction recess portion 59 having a substantially trapezoidal shape was prepared by a laser scriber through a manufacturing process similar to the manufacturing process of the aforementioned second embodiment, as shown in FIG. 23. The length of the upper portion (upper bottom) of the first cleavage introduction recess portion 59 was about 120 μm, and all of the projected lengths L1 and L2 of left and right inclined surface portions (inner side surfaces) and the length L3 of the bottom (lower bottom) were set to about 40 μm respectively.

When first cleavage introduction recess portions 59 were formed on a wafer in a cycle of about 400 μm (along arrow F in FIG. 20) at this time in order to obtain a semiconductor laser chip having a width of about 200 μm, a large number of cracks were observed between first cleavage introduction recess portions 59 adjacent to each other in the longitudinal direction (along arrow D and along arrow E in FIG. 20), in a state connecting the first cleavage introduction recess portions 59 with each other. The sections of these cracks substantially formed cleavage planes, and the aforementioned cracks were formed in about 40% of the first cleavage introduction recess portions 59, whereby no abnormality was observed in a cleavage step.

On the other hand, a plurality of wafers were prepared while varying the length L0 (=L1+L2+L3) of first cleavage introduction recess portions 59 in the longitudinal direction from about 50 μm to about 150 μm. The length L3 of bottoms (lower bottoms) merely changed longer when L0 was at least about 80 μm, while each first cleavage introduction recess portion 59 had a substantially triangular sectional shape (V-shaped groove) as shown in FIG. 21 when L0 was about 80 μm. Further, the sectional shape in the case where L0 was about 50 μm was substantially triangular similarly to the sectional shape in the aforementioned case of about 80 μm, while the depth D of each first cleavage introduction recess portion 59 (depth of the V-shaped groove) (see FIG. 21) was about 20 μm to about 30 μm.

Then, crack formation rates between the first cleavage introduction recess portions 59 with respect to the length L0 of the first cleavage introduction recess portions 59 in the longitudinal direction and yield rates of bar-shaped cleavage were investigated, as shown in FIG. 24.

Referring to FIG. 24, it was confirmed that the proper length L0 of the first cleavage introduction recess portions 59 in the longitudinal direction is about 50 μm to about 130 μm. In other words, it was confirmed preferable to ensure a length of at least about 70 μm between an end of each first cleavage introduction recess portion 59 (see FIG. 20) and the ridge portion 92a (see FIG. 20), in order to obtain a semiconductor laser chip having a width of about 200 μm.

The aforementioned first cleavage introduction recess portion 59 (see FIG. 22) having a substantially trapezoidal shape is so formed that energy for forming the end of the first cleavage introduction recess portion 59 by laser application or the like is smaller than energy for forming the bottom of the first cleavage introduction recess portion 59 by laser application or the like, whereby a bad influence on the ridge portion 92a (see FIG. 20) close to the end of the first cleavage introduction recess portion 59 is suppressed, and deterioration of the ridge portion 92 can be suppressed. Consequently, the length L0 (see FIG. 22) of the first cleavage introduction recess portion 59 in the longitudinal direction can be formed longer. The first cleavage introduction recess portion 59 (see FIG. 22) is appropriately so formed that an angle θ of left and right inclined surfaces (inner side surfaces) is in the range of about 30° to about 60°, and it was possible to obtain a device having excellent laser characteristics in a case where the first cleavage introduction recess portion 59 was formed with a depth D (see FIG. 22) in the range of about 20 μm to about 60 μm when the thickness of the semiconductor laser chip was in the range of about 100 μm to about 150 μm.

As shown in FIG. 22, the cleavage introduction steps 59a (59c) and 59b (59d) are so formed as to have the steps 97a (97b) and 98a (98b) also on parts of the cleavage planes 97 and 98, whereby separation of end coating films can be suppressed when the end coating films (insulating films consisting of single-layer films or multilayer films) (shown by broken lines in FIG. 22) are formed on an light emitting end surface and a reflecting end surface of the semiconductor laser chip in the cleaved bar-shaped device, for example. In other words, separation caused on a partial region spreads in a wide range when a thin film is formed on the light emitting end surface (reflecting end surface) consisting of a completely planar surface, while the thin films strongly adhere also to the steps 97a (97b) and 98a (98b) when the steps 97a (97b) and 98a (98b) are formed on parts of the cleavage planes 97 and 98 as described above, whereby separation of the end coating films can be inhibited from propagating to adjacent semiconductor laser chips.

Further, such steps 97a (97b) and 98a (98b) are so formed that the end coating films (shown by broken lines) can be inhibited from separation resulting from mechanical stress in bar-shaped cleavage or thermal stress in a case of operating as the semiconductor laser chip.

As to the irregularities of such steps 97a (97b) and 98a (98b) (depths of the steps along arrow F in FIG. 22), at least thicknesses substantially identical to the minimum values (about 50 nm, for example) of the thicknesses of the end coating films are preferable. On the other hand, cavity length deviation may result if the irregularities of the steps 97a (97b) and 98a (98b) are excessively large, whereby the irregularities are preferably set to not more than about 5 nm from tolerance for dispersion of the cavity length, in consideration of a case of mounting the semiconductor laser chip on an optical pickup, for example.

The remaining effects of the fourth embodiment are similar to the aforementioned second embodiment.

The embodiments and Example disclosed this time must be considered as illustrative in all points and not restrictive. The range of the present invention is shown not by the above description of the embodiments and Example but by the scope of claims for patent, and all modifications within the meaning and range equivalent to the scope of claims for patent are included.

For example, while the example of applying the present invention to the GaN-based semiconductor laser chip has been shown in each of the aforementioned embodiments, the present invention is not restricted to this but is also applicable to a semiconductor laser device other than a GaN-based one.

While the example of forming the ridge portion (waveguide) on the region approaching the first side by the distance W0 (=about 30 μm) from the center of the GaN-based semiconductor laser chip (n-type GaN substrate) has been described in each of the aforementioned embodiments, the present invention is not restricted to this but the ridge portion may alternatively be formed on a region approaching the first side by a length other than about 30 μm from the center of the GaN-based semiconductor laser chip. In this case, the ridge portion is preferably formed on a region approaching the first side by at least about 20 μm from the center of the GaN-based semiconductor laser chip. According to this structure, bonding of a metal wire onto the ridge portion can be suppressed also when a generally employed metal wire having a diameter of about 30 μm is bonded to the center of the GaN-based semiconductor laser chip, whereby damage of the ridge portion (waveguide) can be suppressed in bonding.

While the example of forming the cleavage introduction steps on the n-type GaN substrate, the semiconductor layer and the current blocking layer has been shown in each of the aforementioned embodiments, the present invention is not restricted to this but the cleavage introductions steps may not be formed on the n-type GaN substrate, but may be formed only on the semiconductor layer and the current blocking layer.

While the example of forming the first cleavage introduction recess portions so that the centers of the first cleavage introduction recess portions are arranged on the intermediate positions between the adjacent ridge portions (waveguides) in the manufacturing process (singulation process) subsequent to the wafer process for the GaN-based semiconductor laser chip in each of the aforementioned embodiments, the present invention is not restricted to this but the first cleavage introduction recess portions may alternatively be so formed that the centers of the first cleavage introduction recess portions are on positions other than the intermediate positions between the adjacent ridge portions (waveguides). In this case, the first cleavage introduction recess portions may be formed at a prescribed interval from the ridge portions (waveguides).

While the example of employing the n-type GaN substrate linearly provided with the region having a large number of crystal defects has been shown in the aforementioned third embodiment, the present invention is not restricted to this but an n-type GaN substrate provided with a region having a large number of crystal defects in a shape, such as a network shape, for example, other than the linear shape.

While the example of so forming the cleavage introduction steps (first steps) as to have the steps also on parts of the cleavage planes has been shown in the aforementioned fourth embodiment, the present invention is not restricted to this but the aforementioned steps formed also on parts of the cleavage planes may be formed in the aforementioned first to third embodiments other than the aforementioned fourth embodiment.

1. A semiconductor laser device comprising:
a substrate of a nitride-based semiconductor; and
a semiconductor layer of a nitride-based semiconductor formed on said substrate and provided with a waveguide extending in a prescribed direction, wherein
said waveguide is formed on a region approaching a first side from the center of said semiconductor layer, and
a first step is formed from the side of said semiconductor layer on a region opposite to said first side of said waveguide at a prescribed distance from said waveguide, to extend in a direction intersecting with said prescribed extensional direction of said waveguide on an extension of an end surface of said waveguide.

2. The semiconductor laser device according to claim 1, wherein
said first step is formed from the side of said semiconductor layer up to a depth reaching said substrate.

3. The semiconductor laser device according to claim 1, wherein
said first step is so formed that the width in the direction intersecting with said prescribed extensional direction of said waveguide is increased upward.

4. The semiconductor laser device according to claim 1, further comprising a first electrode layer formed on said semiconductor layer, wherein
said first electrode layer is formed at a prescribed interval from said first step.

5. The semiconductor laser device according to claim 1, wherein
a second step is formed from the side of said substrate along said prescribed extensional direction of said waveguide.

6. The semiconductor laser device according to claim 5, wherein
said second step is so formed as to have a length substantially identical to the length between a first end surface and a second end surface of said waveguide.

7. The semiconductor laser device according to claim 5, further comprising a second electrode layer on the lower surface of said substrate, wherein
said second step is so formed as to have a depth reaching a part of the lower surface of said substrate from the side of said second electrode layer.

8. The semiconductor laser device according to claim 1, wherein
a third step is formed from the side of said substrate on the end surface of said waveguide, to extend in the direction intersecting with said prescribed extensional direction of said waveguide.

9. The semiconductor laser device according to claim 8, wherein
said third step is provided on a position opposite to at least said waveguide or said first step.

10. The semiconductor laser device according to claim 9, wherein
said third step is so formed as to have a length substantially identical to the length between a first end surface and a second end surface in the direction intersecting with said prescribed extensional direction of said waveguide.

11. A method of manufacturing a semiconductor laser device, comprising steps of:
forming a semiconductor layer of a nitride-based semiconductor including a plurality of waveguides extending in a prescribed direction on a substrate of a nitride-based semiconductor;
forming a plurality of first cleavage introduction recess portions from the side of said semiconductor layer between said plurality of waveguides to extend in a direction intersecting with said prescribed extensional direction of said waveguides;
performing cleavage along said plurality of first cleavage introduction recess portions; and
performing separation along said prescribed extensional direction of said waveguide so that the semiconductor laser device has said waveguides on a region approaching a first side from the center of said semiconductor layer.

12. The method of manufacturing a semiconductor laser device according to claim 11, wherein
the step of forming the semiconductor layer of a nitride-based semiconductor including said plurality of waveguides includes a step of forming said plurality of waveguides to alternately have two different intervals, and
the step of forming said first cleavage introduction recess portions includes a step of forming said first cleavage introduction recess portions between adjacent said waveguides having a larger interval in said two different intervals.

13. The method of manufacturing a semiconductor laser device according to claim 11, wherein
the step of forming said first cleavage introduction recess portions includes a step of forming said first cleavage introduction recess portions from the side of said semiconductor layer up to a depth reaching said substrate.

14. The method of manufacturing a semiconductor laser device according to claim 13, wherein
the step of forming said first cleavage introduction recess portions includes a step of forming said first cleavage introduction recess portions so that the width in the direction intersecting with said prescribed extensional direction of said waveguides is increased upward.

15. The method of manufacturing a semiconductor laser device according to claim 12, wherein
the step of forming said plurality of waveguides includes a step of forming said plurality of waveguides so that a region having a large number of crystal defects of at least either one of said substrate and said semiconductor layer is positioned between adjacent said waveguides having a larger interval in said two different intervals.

16. The method of manufacturing a semiconductor laser device according to claim 11, further comprising a step of forming a separation introduction recess portion from the side of said substrate along said prescribed extensional direction of said waveguides in advance of the step of performing separation along said prescribed extensional direction of said waveguides.

17. The method of manufacturing a semiconductor laser device according to claim 16, wherein
the step of forming said separation introduction recess portion from the side of said substrate includes a step of forming said separation introduction recess portion to have a length substantially identical to the length between first end surfaces and second end surfaces of said waveguides.

18. The method of manufacturing a semiconductor laser device according to claim 11, comprising a step of further forming a second cleavage introduction recess portion on the lower surface of said substrate to extend in the same direction as said prescribed extensional direction of said first cleavage introduction recess portions in advance of performing cleavage along said plurality of first cleavage introduction recess portions.

19. The method of manufacturing a semiconductor laser device according to claim 18, wherein
the step of forming said second cleavage introduction recess portion on the lower surface of said substrate includes a step of forming said second cleavage introduction recess portion on a position opposite to at least said waveguides or said first cleavage introduction recess portions.

20. The method of manufacturing a semiconductor laser device according to claim 11, wherein
the step of performing separation along said prescribed extensional direction of said waveguides includes a step of performing separation so that said semiconductor laser device has said waveguides on the region approaching said first side from the center of said semiconductor layer and has said first cleavage introduction recess portions on a region opposite to said first side of said waveguides.
